(19) United States
(12) Patent Application Publication
(10) Pub. No.: US 2024/0304755 A1
(43) Pub. Date: Sep. 12, 2024

(54) LIGHT-EMITTING DIODE AND LIGHT-EMITTING DEVICE HAVING THE SAME

(71) Applicant: XIAMEN SAN'AN OPTOELECTRONICS CO., LTD., Xiamen (CN)

(72) Inventors: Shiwei LIU, Xiamen (CN); Jin XU, Xiamen (CN); Chung-ying CHANG, Xiamen (CN); Baojun SHI, Xiamen (CN); Shuijie WANG, Xiamen (CN); Ke LIU, Xiamen (CN)

(21) Appl. No.: 18/667,401

(22) Filed: May 17, 2024

Related U.S. Application Data
(63) Continuation-in-part of application No. PCT/CN2021/131648, filed on Nov. 19, 2021.

(51) Int. Cl. H01L 33/24; H01L 33/08; H01L 33/44

(52) U.S. Cl. CPC H01L 33/24; H01L 33/08; H01L 33/44

(57) ABSTRACT

A light-emitting diode includes a substrate and a semiconductor layered structure that is located on the substrate. The semiconductor layered structure includes at least one light-emitting unit, a semiconductor island-structure, and a trench. The trench is located between the at least one light-emitting unit and the semiconductor island-structure. A light-emitting device includes the light-emitting diode.

### CROSS-REFERENCE TO RELATED APPLICATION

This application is a continuation-in-part (CIP) of International Application No. PCT/CN2021/131648, filed on Nov. 19, 2021, and incorporated by reference herein in its entirety.

### FIELD

The disclosure relates to a light-emitting diode, and more particularly to a light-emitting diode and a light-emitting device using the light-emitting diode.

### BACKGROUND

Light-emitting diodes (LEDs) have advantages such as high light emission efficiency, energy saving, environmentally friendly and long service life, and have been applied to wide variety of different fields such as lighting or back lighting. For example, when packaging a conventional flip-chip LED, a push up needle is used to contact a central area on a front side of the LED.

The conventional flip-chip LED may include an epitaxial structure, a transparent conducting layer, electrodes, electrode pads and a protection layer. The electrode pads and the protection layer are for protecting the epitaxial structure, the transparent conducting layer, and the electrodes. The protection layer is conventionally made of a silicon oxide, or may be a multilayer structure (including alternating two material layers which are respectively made of silicon oxide and titanium oxide) that forms a distributed Bragg reflector.

Because the protection layer is quite fragile when the push up needle contacts the front side of the conventional flip-chip LED, the push up needle may puncture or break the protection layer and expose the epitaxial structure, the transparent conducting layer, or the electrodes underneath. This may damage the conventional flip-chip LED and cause it to malfunction or leak electricity both of which may affect the reliability of the conventional flip-chip LED.

### SUMMARY

Therefore, an object of the disclosure is to provide a light-emitting diode and a light-emitting device that can alleviate at least one of the drawbacks of the prior art.

According to a first aspect of the disclosure, the light-emitting diode includes a substrate and a semiconductor layered structure that is located on the substrate. The semiconductor layered structure includes at least one light-emitting unit, a semiconductor island-structure, and a trench. The trench is located between the at least one light-emitting unit and the semiconductor island-structure.

According to another aspect of the disclosure the light-emitting device includes the light-emitting diode of the first aspect.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1A is a schematic top view illustrating a first embodiment of a light-emitting diode according to the present disclosure.

FIG. 1B is a schematic cross-sectional view of the first embodiment taken from line A-A of FIG. 1A.

FIG. 2A is a schematic top view illustrating a variation of the first embodiment.

FIG. 2B is a schematic cross-sectional view of the variation of the first embodiment taken from line A-A of FIG. 2A.

FIG. 3 is a schematic cross-sectional view of another variation of the first embodiment showing a metallic block directly above a semiconductor island-structure.

FIG. 4 is a schematic cross-sectional view of yet another variation of the first embodiment showing the metallic block in a different location.

FIG. 5 is a schematic top view illustrating a second embodiment of a light-emitting diode according to the present disclosure.

FIG. 6 is a schematic cross-sectional view illustrating the second embodiment taken from line A-A in FIG. 5.

FIG. 7 is a schematic cross-sectional view illustrating a variation of the second embodiment, showing a metallic block directly above a semiconductor island-structure.

FIG. 8 is a schematic cross-sectional view illustrating another variation of the second embodiment showing the metallic block in a different location.

FIG. 9 is a schematic cross-sectional view of the second embodiment taken from line B-B in FIG. 5.

FIGS. 10 to 12 are schematic views illustrating successive steps in a method for making the first embodiment of the light-emitting diode according to the present disclosure.

FIG. 13 is a schematic top view illustrating a third embodiment of the light-emitting diode according to the present disclosure.

FIG. 14 is a schematic cross-sectional view illustrating the third embodiment taken from line A-A in FIG. 13.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

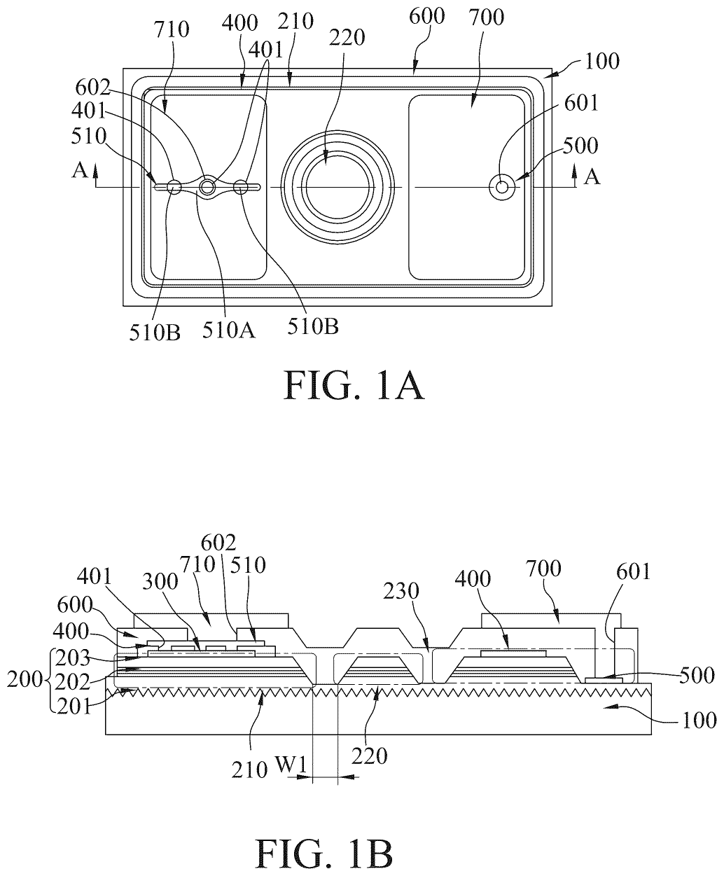

Referring to FIGS. 1A and 1B, a first embodiment of a light-emitting diode according to the present disclosure includes a substrate 100 and a semiconductor layered structure 200. In this embodiment, the light-emitting diode is a flip-chip light-emitting diode (LED); however, this is not a limitation of the disclosure. The semiconductor layered structure 200 is located on the substrate 100, and includes at least one light-emitting unit 210, a semiconductor island-structure 220, and a trench 230 that is located between the at least one light-emitting unit 210 and the semiconductor island-structure 220.

The semiconductor layered structure 200 further includes a first semiconductor layer 201, an active layer 202, and a second semiconductor layer 203 that are sequentially stacked from a bottom surface of the semiconductor layered structure 200. In this embodiment, there is one light-emitting unit 210, and the light emitting unit 210 surrounds the semiconductor island-structure 200. More specifically, the semiconductor island-structure 200 is located at a geometric center of the light-emitting diode, and the trench 230 is located between the light-emitting unit 210 and the semiconductor island-structure 220.

The light-emitting diode further includes a protection layer 600 that covers at least an upper surface and a side wall of the semiconductor island-structure 220. In this embodiment, the protection layer 600 covers an upper surface and a side wall of the light-emitting unit 210, the upper surface and the side wall of the semiconductor island-structure 220, and the trench 230 that is located between the light-emitting unit 210 and the semiconductor island-structure 220.

In this embodiment, an upper surface of the substrate 100, on which the semiconductor layered structure 200 is formed, confronts a front side of the light-emitting diode. In other words, the semiconductor island-structure 220 is located at a geometric center on the front side of the light-emitting diode. The semiconductor island-structure 220 is the area where a push up needle will contact the light-emitting diode during a packaging process in the fabrication of the light-emitting diode. If the push up needle punctures or breaks the protection layer 600 covering the semiconductor island-structure 220, a crack in the protection layer 600 may propagate and reach the upper surface and the side wall of the semiconductor island structure 220. The trench 230 located between the light-emitting unit 210 and the semiconductor island-structure 220 may limit the propagation of the cracking, so that the crack may not reach above a light emission area. This helps to prevent electricity leakage and malfunction of the light-emitting diode due to puncturing or damage of the protection layer 600 and increase the reliability of the light-emitting diode.

More concretely, the previously mentioned light emission area is at the light—emitting unit 210 of the semiconductor layered structure 200. The light-emitting unit 210 is formed from first portions of the first semiconductor layer 201, the active layer 202, and the second semiconductor layer 203. As shown in FIG. 1A, the light-emitting unit 210 surrounds a periphery of the semiconductor island-structure 220.

In one embodiment, the trench 230 has a bottom surface that exposes the semiconductor layered structure 200. Referring to FIG. 1B, in other embodiments, the bottom surface of the trench 230 is located below the active layer 202, this may decrease the likelihood of cracks propagating to the light emission area and affecting electrical characteristics thereof when the protection layer 600 is punctured by the push up needle. In other words, the island structure 220 does not emit light when the light-emitting diode is powered with electricity. In some embodiments, the bottom surface of the trench 230 exposes the first semiconductor layer 201, and the semiconductor island-structure 220 may be formed from second portions of the first semiconductor layer 201, the active layer 202, and the second semiconductor layer 203. In other words, the semiconductor island-structure 220 is not formed independently of the light-emitting unit 210 on the substrate 100, but instead the semiconductor island structure 220 and the light-emitting unit 210 are connected via the first semiconductor unit 201.

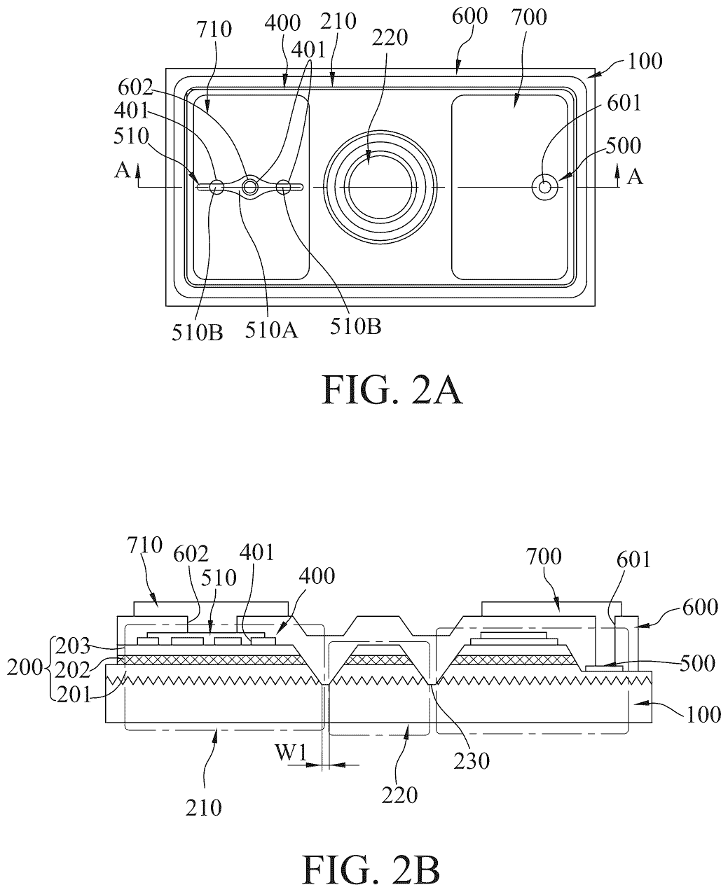

Referring to FIGS. 2A, and 2B, in a variation of the first embodiment, the semiconductor island-structure 220 is located at a geometric center of the light-emitting diode, and the trench 230 is located between the light-emitting unit 210 and the semiconductor island-structure 220. In this case, there are no conducting layers or semiconducting layers between the light-emitting unit 210 and the semiconductor island-structure 220, and the light-emitting unit 210 and the semiconductor island-structure 220 are independently formed on the substrate 100. The bottom surface of the trench 230 is located on the substrate 100. In this embodiment, because the trench 230 is deeper, and the semiconductor island-structure 220 and the light-emitting unit 210 are independently formed, the risk of electrical leakage happening when the protection layer 600 is punctured or damaged by the push needle is even lower, and the light-emitting diode is more reliable.

Referring to FIG. 2B, in this embodiment, the first portions of the first semiconductor layer 201, the active layer 202 and the second semiconductor layer 203 forming the light-emitting unit 210 have the same thickness as the second portions forming the semiconductor island-structure 220. The light-emitting unit 210 has a thickness that ranges from 3 μm to 10 μm.

Referring to FIGS. 2A to 4, the light-emitting unit 210 has a first part of the semiconductor layered structure 200, and the semiconductor island-structure 220 has a second part of the semiconductor layered structure 200. The semiconductor island-structure 220 has a height that is lower than a height of the light-emitting unit 210. In some embodiments, the semiconductor island-structure 220 has a height that is no greater than the height of the light-emitting unit 210. The first part of the semiconductor layered structure 200 includes the first portions of the first semiconductor layer 201, the active layer 202, and the second semiconductor layer 203; and the second part of the semiconductor layered structure 200 has the second portions of the first semiconductor layer 201, the active layer 202, and the second semiconductor layer 203.

The light-emitting unit 210 and the semiconductor island-structure 220 may be formed by first forming the semiconductor layered structure 200 on the substrate 100, and then etching an upper surface of the semiconductor layered structure 200 towards the substrate 100 to form an independent light-emitting unit 210 and the semiconductor island-structure 220. Furthermore, in some embodiments, the semiconductor island-structure 220 may be further etched so that the semiconductor island-structure 220 has a height that is less than the height of the light-emitting unit 210.

In some embodiments, when viewing the semiconductor island-structure 220 from above the substrate 100, the semiconductor island-structure 220 may be observed to have a circular shape or a polygonal shape. However, this is not a limitation of the disclosure. In some embodiments, an upper surface of the semiconductor island-structure 220 opposite to the substrate 100 has a minimum dimension of at least 30 μm. In some embodiments, the minimum dimension of the upper surface of the semiconductor island-structure 220 is designed according to the dimension of the push up needle. In some embodiments, the minimum dimension of the upper surface of the semiconductor island-structure 220 ranges from 50 μm to 80 μm. In this embodiment, the semiconductor island-structure 220 when viewed from above the substrate 100 has a circular shape. Additionally, when viewed from a side aspect, the semiconductor island-structure 220 has a tapered profile, whereby a diameter of the upper surface of the semiconductor island-structure 220 is less than a diameter of a bottom cross-section of the semiconductor island-structure 220.

In some embodiments, the trench 230 is tapered in a top to bottom direction. The trench 230 has a bottom surface with a width W1 that is no less than 3 μm wide on the bottom surface of the trench 230.

In this embodiment, the first semiconductor layer 201 is an N-type semiconductor layer, the active layer 203 is a multiple quantum well structure and emits blue, red, green light, ultraviolet radiation or infrared radiation, and the second semiconductor layer 203 is a P-type semiconductor layer. The semiconductor layered structure 200 may have other structural elements that improve the characteristics of the light-emitting diode. For example, an un-doped semiconductor layer that has a thickness ranging from 3 μm to 15 μm.

The light-emitting diode further includes a first electrode pad 700 and a second electrode pad 710. The first electrode pad 700 is disposed on the protection layer 600 and passes through the protection layer 600 to be electrically connected with the first semiconductor layer 201 of the light-emitting unit 210. The second electrode pad 710 is disposed on the protection layer 600 and passes through the protection layer 600 to be electrically connected with the second semiconductor layer 203 of the light-emitting unit 210.

When the light-emitting diode is installed on a printed circuit board (PCB) for application, the first electrode pad 700 and the second electrode pad 710 may be electrically connected to electrodes of the PCB via reflow soldering or hot pressing. The first electrode pad 700 and the second electrode pad 710 may be electrically connected to the electrodes of the PCB via connection layers that include tin. This may avoid the use of solder paste for connecting the first and second electrode pads 700, 710 to the electrodes of the PCB.

Each of the first electrode pad 700 and the second electrode pad 710 may include an adhesion layer, a reflection layer, a blocking layer, and a gold layer. For example, the adhesion layer may be a titanium layer or a chromium layer, the reflection layer may be an aluminum layer, and the blocking layer may be a nickel layer or a composite layer including repeating layers of nickel and platinum. The blocking layer is used to prevent connection layers that include tin from diffusing into internal structure of the light-emitting diode. In some embodiments, the first electrode pad 700 and the second electrode pad 710 may include a thick tin layer above the gold layer.

Referring to FIGS. 1A and 2A, the semiconductor island-structure 220 is located between the first electrode pad 700 and the second electrode pad 710. Neither one of the first electrode pad 700 nor the second electrode pad 710 covers the semiconductor island structure 220.

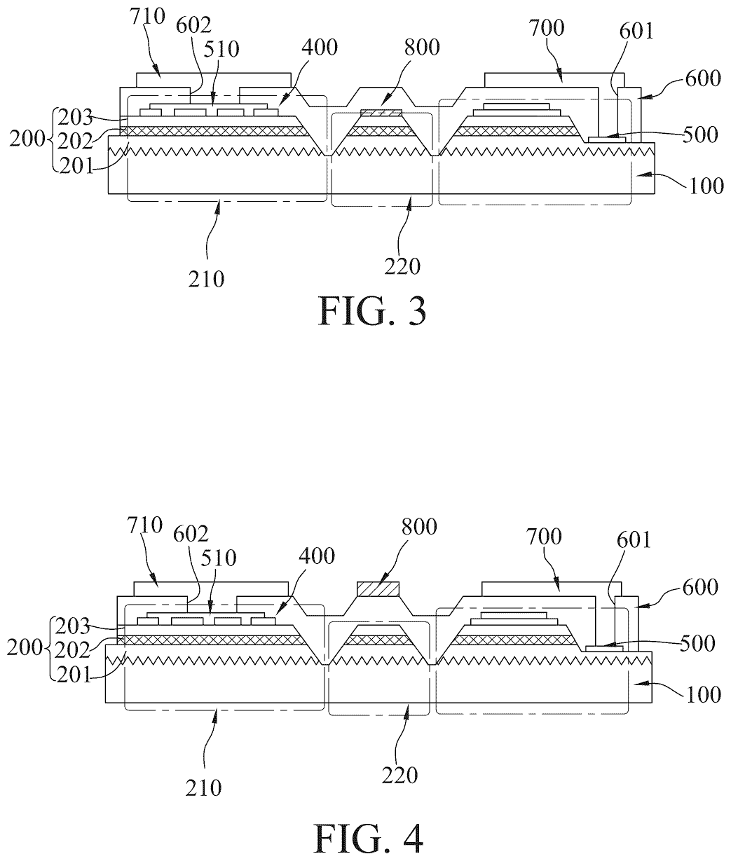

FIGS. 3 and 4 show two other variations of the first embodiments, respectively. In some embodiments, referring to FIGS. 3 and 4, the light-emitting diode includes a metallic block 800 disposed on the semiconductor island-structure 220. The metallic block 800 is somewhat ductile and can absorb a certain amount of force from the push up needle. In some embodiments, the metallic block 800 has a thickness that ranges from 0.5 μm to 10 μm. In some embodiments, the metallic block 800 has a thickness that ranges from 1 μm to 3 μm. In this embodiment, the metallic block 800 may be made of any one of Gold (Au), titanium (Ti), aluminum (Al), chromium (Cr), platinum (Pt), titanium tungsten (TiW), and nickel (Ni) or any combination or combinations thereof; however, this is not a limitation of the disclosure.

Referring to FIG. 3, in this embodiment, the metallic block 800 directly contacts the upper surface of the semiconductor island-structure 220. The protection layer 600 is locate above the metallic block 800. More specifically, the metallic block 800 covers the upper surface of the semiconductor island-structure 220. In some other embodiments, the metallic block 800 may cover the upper surface and at least a portion of the side wall of the semiconductor island-structure 220 (not shown in the Figures).

Referring to FIG. 4, in some embodiments, the metallic block 800 is located on an upper surface of the protection layer 600, and is located above the semiconductor island-structure 220. In other words, the protection layer 600 has a portion that is located between the metallic block 800 and the semiconductor island structure 220. In some embodiments, the metallic block 800 is made of the same material and has the same thickness as the first electrode pad 700, and the second electrode pad 710. The metallic block 800 is located between the first electrode pad 700, and the second electrode pad 710, and is spaced apart from the first and second electrode pads 700, 710. When viewing the semiconductor island-structure 220 from above the substrate 100, it is noticeable that the metallic block 800 has a width that is no greater than a width of the semiconductor island-structure 220.

It should be noted that, the metallic block 800 should be considered an optional feature since the design of the semiconductor island-structure 220 already offers some protection against the propagation of cracks from the protection layer 600 if the push up needle punctures the protection layer 600.

In some embodiments, the substrate 100 is a transparent substrate. For example, the substrate 100 may be a sapphire substrate. In some embodiments, the substrate 100 may be a sapphire substrate with a patterned upper surface or a sapphire substrate with a heterogeneous patterned upper surface that may be made of silicon oxide. The patterns may have a height that ranges from 1 μm to 3 μm, and a width that ranges from 1 μm to 4 μm. The substrate 100 includes an upper surface, a lower surface and a side surface. Light emitted from the active layer 202 may radiate outward from the side surface and the lower surface of the substrate 100. In some embodiments, the substrate 100 has a thickness that is greater than 60 μm; for example, 80 μm, 120 μm, 150 μm, or 250 μm.

Referring to FIGS. 1A to 4, in some embodiments, the semiconductor layered structure 200 of the light-emitting diode has a mesa that exposes the first semiconductor layer 201, and a first electrode 500 is formed on the mesa.

The light-emitting unit 210 further includes a transparent conductive layer 400 disposed on the second semiconductor layer 203 that may be made of indium tin oxide; however, this is not a limitation of the disclosure. The transparent conductive layer 400 includes at least one opening 401 that partially exposes the second semiconductor layer 203. A second electrode 510 is formed on the transparent conductive layer 400, passes through the opening and is electrically connected to the second semiconductor layer 203.

The second electrode 510 includes a block electrode portion 510A and at least one strip electrode portion 5108 that extends from the block electrode portion 510A. The block electrode portion 510A and/or the at least one strip electrode portion 510B passes through the at least one opening 401 of the transparent conductive layer 400, and electrically connects with the second semiconductor layer 203. This improves adhesion of the second electrode 510.

When viewing the transparent conductive layer 400 and the second electrode 510 from above the substrate 100, the at least one opening 401 of the transparent conductive layer 400 has a diameter that is greater than a width of the strip electrode portion 5108 of the second electrode 510; and the at least one opening 401 of the transparent conductive layer 400 has a diameter that is less than a width of the block electrode portion 510A of the second electrode 510 so that an edge of the block electrode portion 510A is disposed on an upper surface of the transparent conductive layer 400.

The first electrode 500 and the second electrode 510 may each include an adhesion layer, a reflection layer, and a blocking layer. The adhesion layer may be a chromium layer or a titanium layer. The reflection layer may be an aluminum layer. The blocking layer may be a composite layer including repeating layers of titanium and platinum.

The protection layer 600 has a first through hole 601 and a second through hole 602 that respectively are located above the first electrode 500 and the second electrode 510. The first electrode pad 700 is disposed on the protection layer 600, and passes through the first through hole 601 to be electrically connected to the first electrode 500. The second electrode pad 710 is disposed on the protection layer 600, and passes through the second through hole 602 to be electrically connected to the second electrode 510. In some embodiments, as shown in FIGS. 2B and 3, the first electrode pad 700 and the second electrode pad 710 are positioned to prevent the metallic block 800 from being covered.

The protection layer 600 may be a single layered insulation layer, or a distributed Bragg reflector, however, this is not a limitation of the protection layer 600. The protection layer 600 may be made from at least two materials of SiO₂, TiO₂, ZnO₂, ZrO₂, and Cu₂O₃. The protection layer 600 may be made into a distributed Bragg reflector via physical vapor deposition (PVD) or ion beam sputtering (IBS) from two different materials disposed in alternating layers.

A high voltage flip-chip light-emitting diode (LED) is a variant design of the conventional flip-chip LED. This type of LED has a plurality of same sized distributed LED portions which are electrically connected in series or parallel. The distributed LED portions are segmented via a plurality of trenches that may be located close to a central area of the high voltage flip-chip LED. When the high voltage flip-chip LED is being transferred a push up needle contacts the central area of the high voltage flip-chip LED, and may puncture an insulation layer of the high voltage flip-chip LED. This could cause moisture to enter the internal structure of the high voltage flip-chip LED and cause aging and malfunction after sustained use.

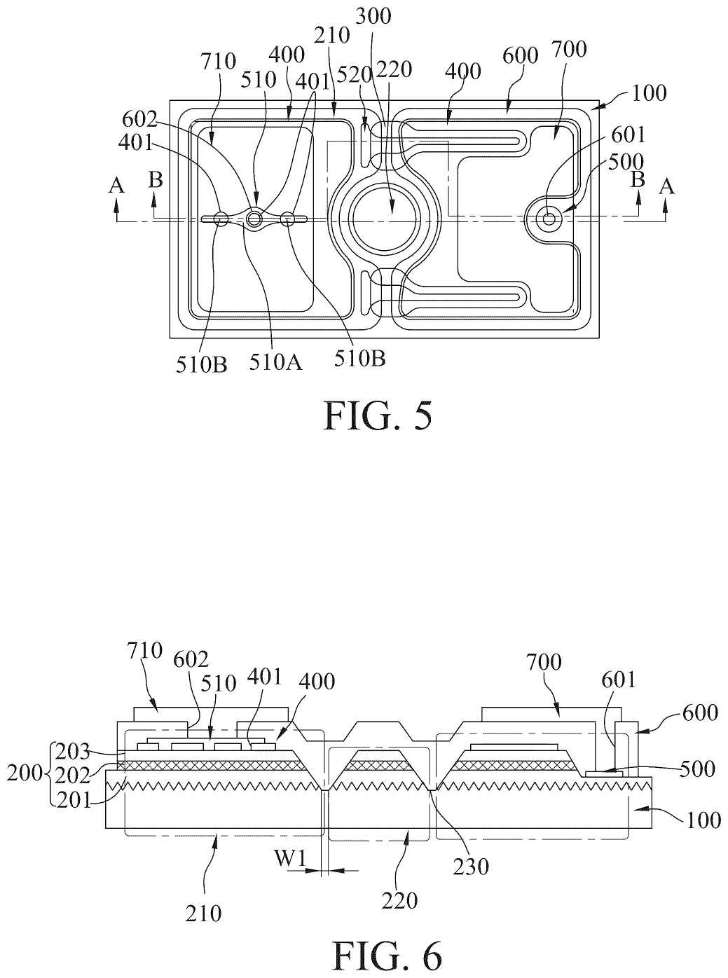

Referring to FIGS. 5 to 9, a second embodiment, of a light-emitting diode according to the present disclosure is a high voltage flip-chip LED.

The second embodiment is similar to the first embodiment, and includes the substrate 100, and the semiconductor layered structure 200. However, in the second embodiment, the semiconductor layered structure 200 is formed on the substrate 100, includes a plurality of light-emitting units 210, and includes the semiconductor island-structure 220. The plurality of light-emitting units 210 are spaced apart from each other, arranged along a preset direction, and each two adjacent ones of the light-emitting units 210 are electrically connected. The semiconductor island-structure 220 is located between two adjacent ones of the plurality of light-emitting units 210 at a central area of the light-emitting diode, and the trench 203 is presented between the semiconductor island-structure 220 and each of the two adjacent ones of the light-emitting units 210. More specifically, the semiconductor island-structure 220 is located at a geographic center of the light-emitting diode and between the two adjacent ones of the plurality of light-emitting units 210. In this embodiment, the geographic center of the light-emitting diode is a central location of the light-emitting diode when viewing the semiconductor island-structure 220 from above the substrate 100. In this embodiment, there are an even number of light-emitting units 210; however, this is not a limitation of the disclosure, and in other embodiments there may be an odd number of light-emitting units 210.

The protection layer 600 covers the upper surface and the side wall of each of the light-emitting units 210, the upper surface and the side wall of the semiconductor island-structure 220, and the trench 230 located between the semiconductor island-structure 220 and the light-emitting units 210.

The first electrode pad 700 is disposed on the protection layer 600, and passes through the protection layer 600 to be electrically connected with a first one (i.e., the most forward one) of the light-emitting units 210. The second electrode pad 710 is disposed on the protection layer 600, and passes through the protection layer 600 to be electrically connected to a last one (i.e., the most rearward one) of the light-emitting units 210. In some embodiments, the trench 230 is tapered in in a top to bottom direction. The bottom surface of the trench 230 has a width no less than 3 μm and no greater than 15 μm.

In some embodiments, the semiconductor island-structure 220 is formed from the same semiconductor layers with the same thicknesses as the semiconductor layers that form the light-emitting units 210. The light-emitting units 210 have a thickness that ranges from 3 μm to 10 μm.

Referring to FIGS. 6 to 8, each of the light-emitting units 210 has a first part of the semiconductor layered structure 200, the semiconductor island-structure 220 has a second part of the semiconductor layered structure 200. The semiconductor island-structure 220 has a height that is no greater than any one of the heights of the light-emitting units 210. The height of the semiconductor island-structure 220 is no greater than a height of the first part of the semiconductor layered structure 200 of each of the light-emitting units 210. The first part of the semiconductor layered structure 200 includes first portions of the first semiconductor layer 201, the active layer 202, and the second semiconductor layer 203, and the second part of the semiconductor layered structure 200 includes second portions of the first semiconductor layer 201, the active layer 202, and the second semiconductor layer 203. In this embodiment, the first semiconductor layer 201 is an N-type semiconductor layer, the active layer 202 is a multiple quantum well structure and can emit blue light, red light, green light, ultraviolet radiation or infrared radiation. The second semiconductor layer 203 is a P-type semiconductor layer. Furthermore, it should be noted that the first part of the semiconductor layered structure 200 may include other structural layers that enhance the characteristics of the light-emitting diode.

The plurality of light-emitting units 210 and the semiconductor island-structure 220 are formed in a process as described below. First a semiconductor layered structure 200 is formed on the substrate 100. The semiconductor layered structure 200 is then etched in the direction of the substrate 100 from a surface of the semiconductor layered structure 200 to form the plurality of light-emitting units 210 and the semiconductor island-structure 220. In some embodiments, the semiconductor island-structure 220 is further etched so that the semiconductor island-structure 220 has a height that is no greater than a height of any one of the light-emitting units 210.

When viewing the semiconductor island-structure 220 from above the substrate 100, the semiconductor island structure 220 may be, but is not limited to a circular shape or a polygonal shape, and the upper surface of the semiconductor island-structure 220 has a minimum dimension of at least 30 μm. In some embodiments, the semiconductor island-structure 220 can be designed to have minimum dimensions matching the dimensions of the push up needle. In some embodiments, the upper surface of the semiconductor island-structure 220 has the minimum dimension of at least 40 μm. In other embodiments, the upper surface of the semiconductor island-structure 220 has the minimum dimension of at least 50 μm. In some embodiments, the upper surface of the semiconductor island-structure 220 has a maximum dimension of 80 μm. In this embodiment, when viewing the semiconductor island-structure 220 from above the substrate 100, the semiconductor island structure 220 has a circular shape. Additionally, the upper surface and the bottom cross-section of the semiconductor island structure 220 are both circular, and a diameter of the upper surface is smaller than a diameter of the bottom cross-section.

In some embodiments, the light-emitting diode further includes a metallic block 800 disposed on the semiconductor island-structure 220. The metallic block 800 is somewhat ductile and provides some cushioning against a force applied by the push up needle. The metallic block 800 has a thickness that ranges from 0.5 μm to 10 μm. In some embodiments, the metallic block 800 has a thickness that ranges from 1 μm to 3 μm. In this embodiment, the metallic block 800 may be made of Au, Ti, Al, Cr, Pt, a TiW alloy, Ni or any combination or combinations of the above.

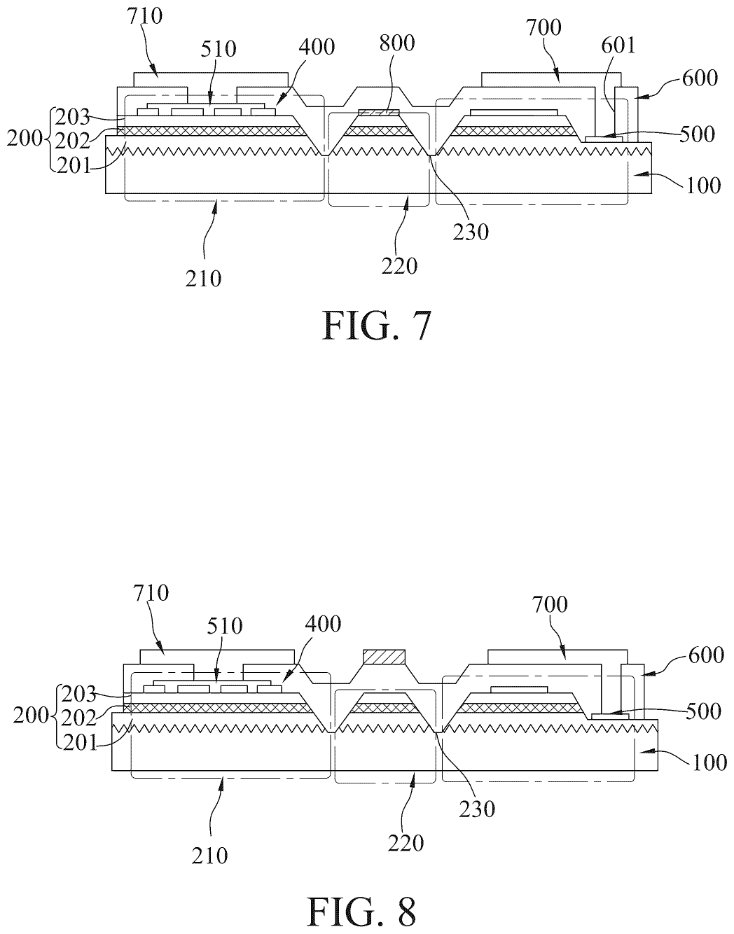

Referring to FIG. 7, the metallic block 800 is directly in contact with the upper surface of the semiconductor island-structure 220. In some embodiments, the metallic block 800 may cover the upper surface and at least a portion of the side wall of the semiconductor island-structure 220 (not shown in the Figures).

Referring to FIG. 8, the protection layer 600 has a portion that is located between the metallic block 800 and the semiconductor island structure 220 or that is located above the semiconductor island structure 220. In some embodiments, the metallic block 800 is made of the same material and has the same thickness as the first electrode pad 700, and the second electrode pad 710. The metallic block 800 is located between the first electrode pad 700 and the second electrode pad 710, and is spaced apart from the first and second electrode pads 700, 710. The metallic block 800 has a thickness that is less than a thickness of the semiconductor island-structure 220.

It should be noted that the metallic block 800 is an optional feature, since the design with the semiconductor island structure 220 already provides some protection against propagation of cracking of the protection layer 600 above the light-emitting units 210.

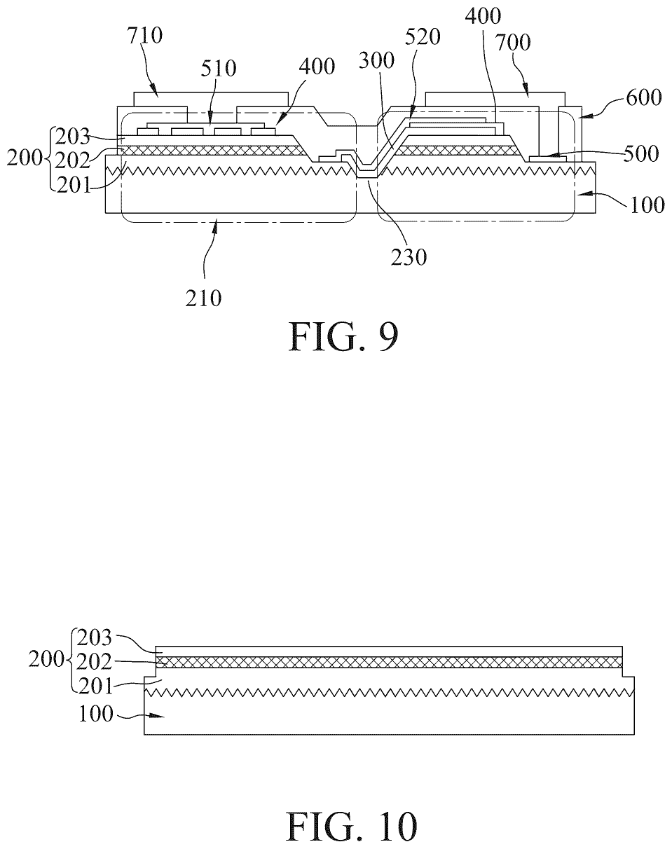

Referring to FIG. 9, in some embodiments, the light-emitting diode includes a current blocking layer 300. In each pair of two adjacent ones of the light-emitting units 210, the current blocking layer 300 extends from the second semiconductor layer 203 on a right one (i.e., a forward one) of each pair of the light-emitting units 210 to the first semiconductor layer 201 on a left one (i.e. a rearward next one) of each pair of the light-emitting units 210. The current blocking layer 300 may be made of silicon oxide, silicon nitride, silicon carbide, or silicon oxynitride, or a combination or combinations of the above.

The first electrode 500 is disposed on the first one of the light-emitting units 210, and is electrically connected to the first semiconductor layer 201 on the light-emitting unit 210.

The second electrode 510 is disposed on a last one of the light-emitting units 210. The transparent conducting layer 400 is formed on the second semiconductor layer 203 on each of the light-emitting units 210. The transparent conducting layer 400 may be made of indium tin oxide, however, this is not a limitation of the disclosure. The transparent conducting layer 400 has at least one opening 401 that exposes a portion of the second semiconductor layer 203. The second electrode 510 passes through the at least one opening 401 to electrically connect with the second semiconductor layer 203 of the last one of the light-emitting units 210.

The second electrode 510 includes a block electrode portion 510A and at least one strip electrode portion 5108 that extends from the block electrode portion 510A. The block electrode portion 510A and/or the at least one strip electrode portion 5108 passes through the at least one opening 401 of the transparent conductive layer 400, and electrically connects with the second semiconductor layer 203. This improves adhesion of the second electrode 510.

When viewing the transparent conductive layer 400 and the second electrode 510 from above the substrate 100, the at least one opening 401 of the transparent conductive layer 400 has a diameter that is greater than a width of the strip electrode portion 510B of the second electrode 510; and the at least one opening 401 of the transparent conductive layer 400 has a diameter that is less than a width of the block electrode portion 510A of the second electrode 510 so that an edge of the block electrode portion 510A is disposed on an upper surface of the transparent conductive layer 400.

Each of the two adjacent ones of the light-emitting units 210 is connected via an interconnecting electrode 520 (see FIG. 9). More specifically, in each of the two adjacent ones of the light-emitting units 210, the transparent conducting layer 400 on the right one (i.e., the forward one) of the light-emitting units 210 covers the current blocking layer 300 above the second semiconductor layer 203. The interconnecting electrode 520 extends from the transparent conducting layer 400 on the forward one of the two light-emitting units 210 to the first semiconductor layer 201 on the rearward next one of the two light-emitting units 210.

The first electrode 500, the second electrode 510, and the interconnecting electrode 520 may each include an adhesion layer, a reflection layer, and a blocking layer. The adhesion layer may be made of a chromium layer or a titanium layer. The reflection layer may be made an aluminum layer. The blocking layer may by a composite layer including repeating layers of titanium and platinum.

The protection layer 600 has a first through hole 601 and a second through hole 602 that respectively are located above the first electrode 500 and the second electrode 510. The first electrode pad 700 is disposed on the protection layer 600, and passes through the first through hole 601 to be electrically connected to the first electrode 500. The second electrode pad 710 is disposed on the protection layer 600, and passes through the second through hole 602 to be electrically connected to the second electrode 510.

The protection layer 600 may be a single layered insulating layer or a distributed Bragg reflector. However, this is not a limitation of the disclosure. In this embodiment, the protection layer 600 is a distributed Bragg reflector made via physical vapor deposition (PVD) or ion beam sputtering (IBS) of at least two different materials disposed in alternating layers. The at least two materials may be selected from SiO₂, TiO₂, ZnO₂, ZrO₂, Cu₂O₃.

The light-emitting diode of the present disclosure may be used for lighting or displays, and are suitable for applications requiring smaller LEDs that do not require high brightness but must have good reliability. For example, back lighting, displays, RGB LED displays.

In the case of back lighting applications, direct back lit displays have improved brightness uniformity and contrast within a light mixing distance compared to conventional back lighting designs. This is accomplished via having a high density mass of flip-chip LEDs to allow light adjustment in a smaller area. It should be noted that the direct back lit displays also have the advantage of not requiring extra lenses to redistribute light and can therefore be made thinner, have higher color reproduction and be more energy efficient. The current disclosure improves yield rates for mass transfer of flip-chip LEDs by featuring the semiconductor island-structure 220 and improves the reliability of the light-emitting diode.

A method for making the first embodiment of the light-emitting diode includes steps S1, S2, S3 and S4. In this method, the light-emitting diode thus obtained is a flip-chip LED. Referring to FIG. 10, in the step S1, the substrate 100 is provided, and the semiconductor layered structure 200 is formed on the substrate 100. The semiconductor layered structure 200 includes the first semiconductor layer 201, the active layer 202, and the second semiconductor layer 203. The first semiconductor layer 201 is an N-type semiconductor layer. The active layer 202 is a multiple quantum well structure. The second semiconductor layer 203 is a P-type semiconductor layer. In this embodiment, the substrate 100 is a patterned sapphire substrate or an un-patterned sapphire substrate.

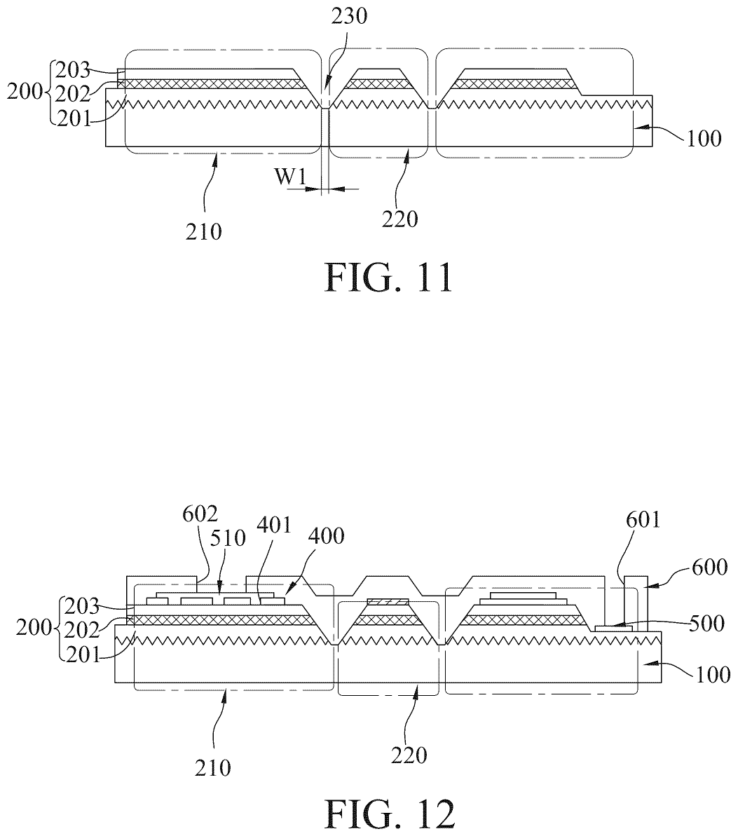

Referring to FIG. 11, in the step S2, the semiconductor layered structure 200 is etched to form a trench 230 that passes through the semiconductor layered structure 200. The trench 230 has a loop shape (e.g., a ring shape) and divides the semiconductor layered structure 200 into the light-emitting unit 210 and the semiconductor island-structure 220 that are independent of each other. The trench 230 surrounds a periphery of the semiconductor island-structure 220.

The trench 230 is tapered in the top to bottom direction and has a width W1.

When viewing the semiconductor island-structure 220 from above the substrate 100, the semiconductor island-structure 220 has a circular shape or a polygonal shape. Additionally, the upper surface of the semiconductor island-structure 220 has a minimum dimension of at least 30 μm. In some embodiments, the dimensions of the semiconductor island-structure 220 can be designed according to the dimensions of the push up needle. In some embodiments, the upper surface of the semiconductor island-structure 220 may have a minimum dimension of at least 40 μm. In other embodiments, the upper surface of the semiconductor island-structure 220 may have a minimum dimension of at least 50 μm. In this embodiment, the semiconductor island structure 220 is formed to have a tapered profile, whereby the diameter of the upper surface of the semiconductor island structure 220 is smaller than a diameter of the bottom cross-section of the semiconductor island structure 220.

Referring to FIG. 12, in the step S3, the protection layer 600 is formed on the light-emitting unit 210, the semiconductor island-structure 220, and the trench 230. The protection layer 600 may be a distributed Bragg reflector or a single layered insulation layer.

More specifically, the light-emitting unit 210 includes the first part of the semiconductor layered structure 200, and the transparent conductive layer 400 is formed on the first part of the semiconductor layered structure 200. The transparent conductive layer 400 has at least one opening 401 that exposes the second semiconductor layer 203. The transparent conductive layer 400 is made of a transparent conductive material, for example, indium tin oxide.

The first part of the semiconductor layered structure 200 has a mesa that exposes a portion of the first semiconductor layer 201. The first electrode 500 is formed on the mesa. The second electrode 510 is formed on the transparent conducting layer 400. The second electrode 510 passes through the at least one opening 401 to electrically connect with the second semiconductor layer 203.

The second electrode 510 includes a block electrode portion 510A and at least one strip electrode portion 5108 that extends from the block electrode portion 510A (see also FIG. 2A). The block electrode portion 510A and/or the at least one strip electrode portion 5108 passes through the at least one opening 401 of the transparent conductive layer 400, and electrically connects with the second semiconductor layer 203. This improves adhesion of the second electrode 510.

When viewing the transparent conductive layer 400 and the second electrode 510 from above the substrate 100, the at least one opening 401 of the transparent conductive layer 400 has a diameter that is greater than a width of the strip electrode portion 5108 of the second electrode 510; and the at least one opening 401 of the transparent conductive layer 400 has a diameter that is less than a width of the block electrode portion 510A of the second electrode 510 so that an edge of the block electrode portion 510A is disposed on an upper surface of the transparent conductive layer 400.

The protection layer 600 is etched to form two through holes 601, 602 respectively above the first and second electrodes 500, 510. The through holes 601, 602 are respectively used to form the first electrode pad 700 that corresponds to the first electrode 500, and the second electrode pad 710 that corresponds to the second electrode 510.

In the step S4, the first electrode pad 700, and the second electrode pad 710 are formed and are electrically connected to the light-emitting unit 210. After performing this step, a light-emitting diode as shown in FIGS. 2A and 2B is obtained.

In some embodiments, the method further includes, while forming the first electrode 500 and the second electrode 510, simultaneously forming the metallic block 800 (see FIG. 3) on the semiconductor island-structure 220. The metallic block 800 covers the upper surface of the semiconductor island-structure 220, or the upper surface and at least a portion of the side wall of the semiconductor island-structure 220. The metallic block 800 has a thickness that ranges from 0.5 μm to 10 μm. In some embodiments, the metallic block 800 may have a thickness that ranges from 1 μm to 3 μm. In this embodiment, the metallic block 800 may be made of the same material as the first electrode 500 and the second electrode 510. After performing the above step, the light-emitting diode as shown in FIG. 3 may be obtained.

In some other embodiments, the method further includes, while forming the first electrode pad 700 and the second electrode 710, simultaneously forming the metallic block 800 (see FIG. 4) on the protection layer 600 above the semiconductor island-structure 220. The metallic block 800 has a thickness that ranges from 0.5 μm to 10 μm. In some embodiments, the metallic block 800 may have a thickness that ranges from 1 μm to 3 μm. In this embodiment, the metallic block 800 may be made of the same material as the first electrode pad 700 and the second electrode pad 710. After performing the above step, the light-emitting diode as shown in FIG. 4 may be obtained.

Another method for making the second embodiment of the light-emitting diode (see FIG. 5) includes steps S10, S20 and S30. In the step S10, a substrate 100 is provided, and a plurality of light-emitting units 210 are formed to be spaced apart and arranged according to a preset direction on the substrate 100.

Two adjacent ones of the light-emitting units 210 are electrically connected. A semiconductor island-structure 220 is located between two adjacent ones of the light-emitting units 210 at a central area of the light-emitting diode, and the trench 203 is presented between the semiconductor island-structure 220 and each of the two adjacent ones of the light-emitting units 210. The number of plurality of light-emitting units 210 may be an even number or an odd number. The semiconductor island structure 220 is located at a geometric center of the light-emitting diode, and the light-emitting units 210 are arranged close to each other.

In more detail, the semiconductor layered structure 200 is formed on the substrate 100. The semiconductor layered structure 200 includes a first semiconductor layer 201, an active layer 202, and a second semiconductor layer 203 that are sequentially stacked from a bottom surface of the semiconductor layered structure 200. It should be noted that, the first semiconductor layer 201 is an N-type semiconductor layer, the active layer 202 is a multiple quantum well structure, and the second semiconductor layer 203 is a P-type semiconductor layer. The semiconductor layered structure 200 is etched to form the light-emitting units 210 respectively having the first parts of the semiconductor layered structures 200. Each of two adjacent ones of the light-emitting units 210 is spaced apart by the trench 230. The semiconductor island-structure 220 is located at a center of the substrate 100 and the trench 230 surrounds a periphery of the semiconductor island-structure 220.

The trench 230 is tapered in a top to bottom direction and has a width W1. When viewing the semiconductor island-structure 220 from above the substrate 100, the semiconductor island-structure 220 has a circular shape or a polygonal shape. In addition, the upper surface of the semiconductor island-structure 220 has a minimum dimension of at least 30 μm. In some embodiments, the minimum dimension of the upper surface of the semiconductor island-structure 220 is designed according to the dimension of the push up needle. In some embodiments, the upper surface of the semiconductor island-structure 220 has the minimum dimension of at least 50 μm. The semiconductor island-structure 220 also has a tapered profile, a diameter of the upper surface of the semiconductor island-structure 220 is smaller than a diameter of the bottom cross-section of the semiconductor island-structure 220.

In each pair of two adjacent ones of the light-emitting units 210, the current blocking layer 300 (see FIG. 9) extends from the second semiconductor layer 203 on a right one (i.e., a forward one) of each pair of the light-emitting units 210 through the trench 230 to the first semiconductor layer 201 on a left one (i.e. a rearward next one) of each pair of the light-emitting units 210. The current blocking layer 300 may be made of silicon oxide, silicon nitride, silicon carbide, or silicon oxynitride, or a combination or combinations of the above.

Next, the transparent conductive layer 400 is formed on the second semiconductor layer 203 of each of the light-emitting units 210. The transparent conductive layer 400 may be made of a transparent conducting material, for example indium tin oxide. In each pair of two adjacent light-emitting units 210, the right one of each pair may include the transparent conductive layer 400 that is disposed on the current blocking layer 300 above the second semiconductor layer 203.

The first electrode 500 is formed on the first one of the light-emitting units 210 on the first semiconductor layer 201.

The second electrode 510 is formed on the transparent conductive layer 400 on the last one (i.e., the most rearward) of the light-emitting units 210. The second electrode 510 passes through the at least one opening 401 of the transparent conductive layer 400 to electrically connect with the second semiconductor layer 203.

The second electrode 510 includes a block electrode portion 510A and at least one strip electrode portion 5108 that extends from the block electrode portion 510A (see also FIG. 5). The block electrode portion 510A and/or the at least one strip electrode portion 5108 passes through the at least one opening 401 of the transparent conductive layer 400, and electrically connects with the second semiconductor layer 203 of the last one of the light-emitting units 210. This improves adhesion of the second electrode 510.

When viewing the transparent conductive layer 400 and the second electrode 510 from above the substrate 100, the at least one opening 401 of the transparent conductive layer 400 has a diameter that is greater than a width of the strip electrode portion 5108 of the second electrode 510, and the at least one opening 401 of the transparent conductive layer 400 has a diameter that is less than a width of the block electrode portion 510A of the second electrode 510 so that an edge of the block electrode portion 510A is disposed on an upper surface of the transparent conductive layer 400.

An interconnecting electrode 520 is formed to connect each pair of two adjacent ones of the light-emitting units 210. The interconnecting electrode 520 extends from the transparent conductive layer 400 on the right one of each pair of the light-emitting units 210 to the first semiconductor layer 201 on a left one of each pair of the light-emitting units 210.

In the step S20, the protection layer 600 is formed on the plurality of light-emitting units 210, the semiconductor island structure 220, and the trench 230. The protection layer 600 may be a single layered insulating layer or a distributed Bragg reflector.

The protection layer 600 is then etched to form the first through hole 601 and the second through hole 602 respectively above the first electrode 500 and the second electrode 510. The first and second through holes 601, 602 are for the subsequent formation of the first electrode pad 700 that corresponds in location to the first electrode 500, and the second electrode pad 710 that corresponds in location to the second electrode 510.

In a step S30, the first electrode pad 700 is formed in the first through hole 601 to be electrically connected to the first light-emitting unit 210, and the second electrode pad 710 is formed in the second through hole 602 to be electrically connected to the last light-emitting unit 210. After performing this step, a light-emitting diode as shown in FIG. 6 is obtained.

In a variation of the another method, the variant method may further include simultaneously forming the metallic block 800 on the semiconductor island-structure 220 when forming the first electrode 500, the second electrode 510, and the interconnecting electrode 520. The metallic block 800 covers the upper surface of the semiconductor island-structure 220, or the metallic block 800 may cover the upper surface and a portion of the side wall of the semiconductor island-structure 220. The metallic block 800 has a thickness that ranges from 0.5 μm to 10 μm. In some embodiments, the metallic block 800 has a thickness that ranges from 1 μm to 3 μm. In this embodiment, the metallic block 800 may be made of the same material as the first electrode 500, the second electrode 510, or the interconnecting electrode 520. After performing the above step, a light-emitting diode as shown in FIG. 7 is obtained.

In another variation of the another method, the variant method May further include simultaneously forming the metallic block 800 on a surface of the protection layer 600 that is above the semiconductor island structure 220, when forming first electrode pad 700 and the second electrode pad 710. The metallic block 800 may have a thickness that ranges from 0.5 μm to 10 μm. In some embodiments, the metallic block 800 has a thickness that ranges from 1 μm to 3 μm. In this embodiment, the metallic block 800 may be made of the same material as the first electrode pad 700 and the second electrode pad 710. After performing the above step, a light-emitting diode as shown in FIG. 8 is obtained.

In another embodiment of the disclosure, a light-emitting device includes a light-emitting diode or a plurality of light-emitting diodes from any of the embodiments of the present disclosure. The light-emitting device may be a lighting device, a back light device, a display device. For example, the light-emitting device may be used in a lamp, a television, a mobile phone display, a display panel, or a RGB monitor. There may be a few hundred to a few thousand light-emitting diodes collectively installed on a base board or PCB which forms a light emitting area.

By virtue of the design of the semiconductor island-structure 220, and the trench 230 that is located between the light-emitting unit 210 and the semiconductor island-structure 220, if the push up needle punctures the protection layer 600, a crack caused by the puncture will only propagate to the upper surface or side wall of the semiconductor island structure 220, and may be prevented from propagating to the protection layer 600 above the light-emitting unit 210 which may cause electrical leakage. The light-emitting diode thus disclosed if therefore more reliable.

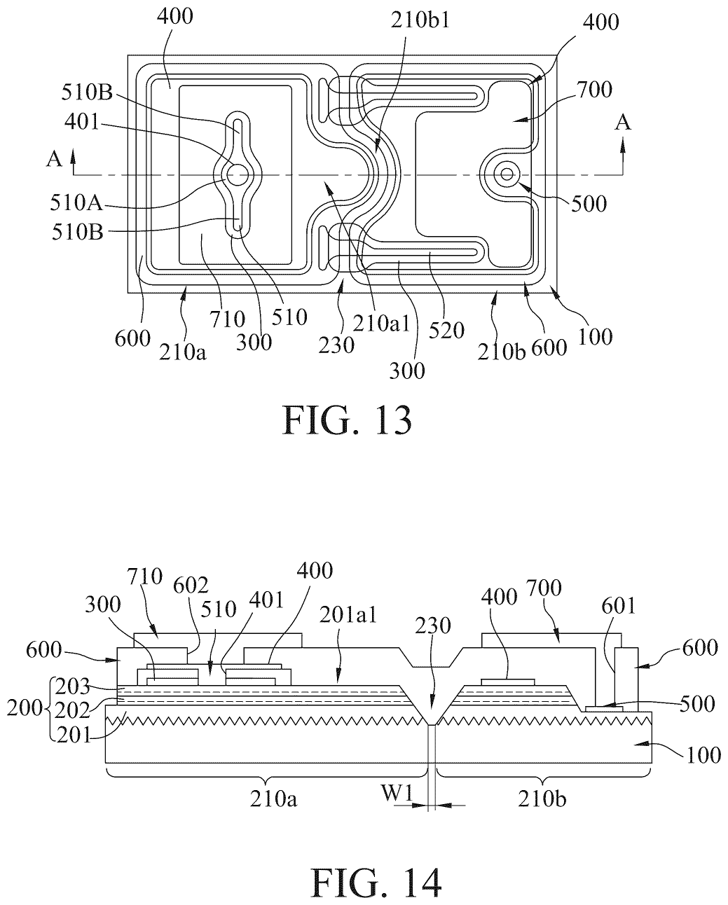

Referring to FIGS. 13 and 14, a third embodiment of the light-emitting diode is similar to the second embodiment, however the differences are described in the following.

The light-emitting diode includes the substrate 100, and the semiconductor layered structure 200 includes a plurality of light-emitting units 210 are formed to be spaced apart and arranged according to a preset direction on the substrate 100. Two adjacent ones of the light-emitting units 210 are electrically connected. In some embodiments, at least two light-emitting units 210 (i.e., a first light-emitting unit 210a, and a second light-emitting unit 210b) are both located on the substrate 100. The semiconductor layered structure 200 further includes the first semiconductor layer 201, the active layer 202, and the second semiconductor layer 203, and the trench 230 is located between the first light-emitting unit 210a, and the second light emitting unit 210b. The trench 230 has the bottom surface that exposes the semiconductor layered structure 200.

The first light-emitting unit 210a has a protruding portion 210a1, and the second light-emitting units 210b has a receding portion 210b1.

The protruding portion 210a1 of the first light-emitting unit 210a is located on a periphery of one side of the first light-emitting unit 210a. When viewing the light-emitting diode from above the substrate 100, the protruding portion 210a1 of the first light-emitting unit 210a extends from the side of the first light-emitting unit 210a and causes the first light-emitting unit 210a to be wider at a cross-section including the protruding portion 210a1 (see FIG. 14).

The protruding portion 210a1 is located near a geometric center of the light-emitting diode when viewing the light-emitting diode from a top view shown in FIG. 13.

The protection layer 600 covers upper surfaces and side walls of each of the first and second light emitting units 210a, 210b, including covering an upper surface and a side wall of the protruding portion 210a1, and covering a section of the trench 230 that is between the protruding portion 210a1 of the first light emitting unit 210a, and the second light emitting unit 210b.

When the push up needle of a transfer machine contacts the light emitting diode that is supported by a non-rigid material such as blue tape, and transfers the light-emitting diode to another device or PCB, the push up needle will contact the protection layer 600 at the protruding portion 210a1 of the first light-emitting unit 210a that is between the first electrode pad 700, and the second electrode pad 710. This setup is much more reliable compared to the conventional setup where the push up needle will contact the protection layer above the trench of the light-emitting diode, the protection layer being liable to be punctured by the push up needle and cause electricity leakage and reduce the reliability of the light-emitting diode. The reliability of the third embodiment is increased due to the design of having the protruding portion 210a1 which provides a flat surface for contact with the push up needle and decreases the likelihood of the push up needle puncturing the protection layer 600 and generating a crack.

Additionally it should be noted that although the design of the protruding portion 210a1 of the first light-emitting unit 210a slightly increases the chance of the push up needle puncturing the protection layer 600 during transfer, the protruding portion 210a1 may still emit light when powered with electricity. This is in contrast to the semiconductor island-structure 220 from the second embodiment which does not emit light when the light-emitting diode is powered with electricity. Therefore the design of the protruding portion 210a1 reduces light loss. Additionally, the interconnecting electrode may be designed to circumvent the area of the protruding portion 210a1 and be made narrower to decrease light absorption.

In other embodiment, the number of light-emitting units 210 may be an even number or an odd number, and be arranged linearly along a direction.

The protruding portion 210a1 of the first light-emitting unit 210a has the same thickness as the semiconductor layered structure 200. A bottom of the protruding portion 210a1 is a portion of a bottom of the semiconductor layered structure 200, and the top surface of the protruding portion 210a1 is a portion of the top surface of the semiconductor layered structure 200.

The semiconductor layered structure 200 includes the first semiconductor layer 201, the active layer 202, and the second semiconductor layer 203. The first semiconductor layer 201 is an N-type semiconductor layer. The active layer 202 is a multiple quantum well structure and may emit blue light, green light, or red light. The active layer 202 may also emit ultra violet or infrared radiation. The second semiconductor layer 203 is a P-type semiconductor layer. Additionally, it should be noted that the semiconductor layered structure 200 may include other structural layers that improve or optimize flip-chip light-emitting diodes.

In this embodiment, the light-emitting element 210 has a thickness ranging from 3 μm to 10 μm.

The protruding portion 210a1 is located on a periphery of the first light-emitting unit 210a. An upper surface of the protruding portion 210a1 (i.e., the upper surface of the second semiconductor layer 203 at the protruding region 210a1) is opposite to the substrate 100 has a minimum dimension of at least 30 μm. That is to say the design of the protruding portion 210a1 increases a dimension of the first light-emitting unit 210a by at least 30 μm (when viewed from above the substrate 100). In some embodiments, the minimum dimension of the upper surface of the protruding portion 210a1 can be designed according to the dimension of the push up needle. In some embodiments, the upper surface of the protruding portion 210a1 has a minimum dimension of at least 50 μm. In some embodiments, the upper surface of the protruding portion 210a1 has a maximum dimension that is no more than 100 μm.

In this embodiment, the protruding portion 210a1 of the first light-emitting unit 210a makes the first light-emitting unit 210a wider. Therefore, the receding portion 210b1 of the second light-emitting unit 210b is made to match the protruding portion 210a1 of the first light-emitting unit 210a.

The receding portion 210b1 of the second light-emitting unit 210b, means the second light-emitting unit 210b is made narrower at the receding portion 210b1.

Referring to FIG. 13, when viewing the light-emitting diode from above the substrate 100, a periphery of the protruding portion 210a1 is non linear, and a periphery of the receding portion 210b1 is also non linear. For example, the periphery of the protruding portion 210a1 may be composed of curved lines and/or multiple straight lines.

The first electrode 500 is disposed on the second light-emitting unit 210b. The first electrode 500 is electrically connected to the first semiconductor layer 201 on the second light-emitting unit 210b.

The second electrode 510 is disposed on the first light-emitting unit 210a. In each of the first and second light-emitting units 210a, 210b, the transparent conductive layer 400 is formed on the second semiconductor layer 203. The transparent conductive layer 400 may be made of indium tin oxide; however, this is not a limitation of the disclosure. The second electrode 510 is located above the transparent conductive layer 400 of the first light-emitting unit 210a. The current blocking layer 300 may be optionally present below the transparent conductive layer 400. The current blocking layer 300 is below the second electrode 510 and can block vertical currents which promote current spreading.

In a variation of the fifth embodiment, at least one opening 401 is formed to pass through the transparent conductive layer 400 and the current blocking layer 300 so as to expose a portion of the second semiconductor layer 203 of the first light-emitting unit 210a. The second electrode 510 is electrically connected to the second semiconductor layer 203 of the first light-emitting unit 210a through the opening 401. The second electrode 510 includes the block electrode portion 510A and the at least one strip electrode portion 510B (that is narrower than the block electrode portion 510A) that extends from the block electrode portion 510A, passes through the at least one opening 401, and electrically connects with the second semiconductor layer 203 of the first light-emitting unit 210a. This improves adhesion of the second electrode 510.

Two adjacent ones of the light-emitting units 210 (e.g., the first and second light emitting-units 210a, 210b) are electrically connected via the interconnecting electrode 520. More specifically, the first light-emitting unit 210a includes the transparent conductive layer 400 that is disposed on the current blocking layer 300 that is above the second semiconductor layer 203. The interconnecting electrode 520 extends from the transparent conducting layer 400 on the first light-emitting unit 210a over the trench 230 to the first semiconductor layer 201 on the second light-emitting unit 210b.

In some embodiments, the transparent conductive layer 400 covers a portion of the protruding portion 210a1, and the interconnecting electrode 520 is located above the protruding portion 210a1 and the transparent conductive layer 400 (not shown in FIG. 14), and extends to the first semiconductor layer 201 on the second light-emitting unit 210b. The interconnecting electrode 520 is a metallic structure and is able to absorb some of the force from the push up needle. The interconnecting electrode 520 has a minimum width that is at least 30 μm.

Referring to FIGS. 13 and 14, in some embodiments, the transparent conductive layer 400 does not cover a portion of the protruding portion 210a1, and the interconnecting electrode 520 is not located above the protruding portion 210a1. In other words, the interconnecting electrode 520 is designed to circumvent the protruding portion 210a1. For example, the interconnecting electrode 520 may be located on a side of the protruding portion 210a1. In this way, the interconnecting electrode 520 may be made narrower which reduces light absorption.

The first electrode pad 700 is disposed on the protection layer 600, and passes through the protection layer 600 to electrically connect with one of the first and second light-emitting units 210a, 210b (the second light-emitting unit 210b, in this embodiment). The second electrode pad 710 is disposed on the protection layer 600, and passes through the protection layer 600 to electrically connect with another one of the first and second light-emitting units 210a, 210b (the first light-emitting unit 210a, in this embodiment).

The protection layer 600 has the first through hole 601 above the first electrode 500, and the second through hole 602 above the second electrode 510. The first electrode pad 700 and the second electrode pad 710 are disposed on the protection layer 600 and are respectively electrically connected to the first electrode 500 and the second electrode 510 via the first through hole 601 and the second through hole 602, respectively.

In some embodiments, the trench 230 has a bottom width W1 that is no less than 3 μm.

The first electrode 500, the second electrode 510, and the interconnecting electrode 520 are metallic electrodes, and can each include an adhesion layer, a reflection layer, and a blocking layer. The adhesion layer may be a chromium layer or a titanium layer, the reflection layer may be an aluminum layer, and the blocking layer may be a composite layer including repeating layers of titanium and platinum.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting diode comprising:
a substrate; and
a semiconductor layered structure located on said substrate, and including at least one light-emitting unit, an semiconductor island-structure, and a trench that is located between said at least one light-emitting unit and said semiconductor island-structure.

2. The light-emitting diode as claimed in claim 1, wherein said trench has a bottom surface that exposes said semiconductor layered structure.

3. The light-emitting diode as claimed in claim 1, wherein:
said semiconductor layered structure further includes a first semiconductor layer, an active layer, and a second semiconductor layer that are sequentially stacked from a bottom surface of said semiconductor layered structure;
a bottom surface of said trench is located below said active layer.

4. The light-emitting diode as claimed in claim 1, wherein a bottom surface of said trench is located on said substrate.

5. The light-emitting diode as claimed in claim 1, wherein said semiconductor island-structure is located at a geometric center of said light-emitting diode.

6. The light-emitting diode as claimed in claim 1, wherein an upper surface of said semiconductor island-structure opposite to said substrate has a minimum dimension of at least 30 μm.

7. The light-emitting diode as claimed in claim 1, wherein when viewing said semiconductor island-structure from above said substrate, said semiconductor island-structure has a circular shape or a polygonal shape.

8. The light-emitting diode as claimed in claim 1, wherein said semiconductor island-structure has a height that is no greater than a height of said at least one light-emitting unit.

9. The light-emitting diode as claimed in claim 1, further comprising a metallic block disposed on said semiconductor island-structure.

10. The light-emitting diode as claimed in claim 9, wherein said metallic block directly contacts an upper surface of said semiconductor island-structure.

11. The light-emitting diode as claimed in claim 9, wherein said metallic block has a thickness that ranges from 0.5 μm to 10 μm.

12. The light-emitting diode as claimed in claim 9, further comprising a protection layer that covers at least an upper surface and a side wall of said semiconductor island structure.

13. The light-emitting diode as claimed in claim 12, wherein said protection layer has a portion that is located between said metallic block and said semiconductor island structure or that is located above said metallic block.

14. The light-emitting diode as claimed in claim 12, wherein:
said light-emitting diode further comprises a first electrode pad and a second electrode pad;
said protection layer covers an upper surface and a side wall of said at least one light-emitting unit;
said at least one light-emitting unit includes a first semiconductor layer, an active layer, and a second semiconductor layer;
said first electrode pad is disposed on said protection layer and passes through said protection layer to be electrically connected with said first semiconductor layer of said at least one light-emitting unit; and
said second electrode pad is disposed on said protection layer and passes through said protection layer to be electrically connected with said second semiconductor layer of said at least one light-emitting unit.

15. The light-emitting diode as claimed in claim 14, wherein said first electrode pad and said second electrode pad are positioned to prevent said metallic block from being covered.

16. The light-emitting diode as claimed in claim 1, wherein:
said at least one light-emitting unit includes one light-emitting unit; and
said light-emitting unit surrounds a periphery of said semiconductor island-structure.

17. The light-emitting diode as claimed in claim 1, wherein:
said at least one light-emitting unit includes a plurality of light-emitting units that are spaced apart from each other.

18. The light-emitting diode as claimed in claim 17, wherein said semiconductor island-structure is located between two adjacent ones of said plurality of light-emitting units.

19. The light-emitting diode as claimed in claim 17, wherein said semiconductor island-structure is located at a geometric center of said light-emitting diode and between two adjacent ones of said plurality of light-emitting units.

20. The light-emitting diode as claimed in claim 17, wherein two adjacent ones of said plurality of light-emitting units are electrically connected.

21. The light-emitting diode as claimed in claim 1, wherein said trench is tapered in a top to bottom direction.

22. A light-emitting device comprising a light-emitting diode as claimed in claim 1.
